(19) United States
(12) Patent Application Publication
(10) Pub. No.: US 2024/0113708 A1
(43) Pub. Date: Apr. 4, 2024

(54) DRIVING CIRCUIT OF HIGH-SIDE TRANSISTOR, CLASS-D AMPLIFIER CIRCUIT USING THE SAME, CONVERTER CONTROLLER CIRCUIT AND HIGH-SIDE SWITCH CIRCUIT

(71) Applicant: Rohm Co., Ltd., Kyoto-shi (JP)

(72) Inventor: Mitsuteru SAKAI, Kyoto-shi (JP)

(21) Appl. No.: 18/474,479

(22) Filed: Sep. 26, 2023

(30) Foreign Application Priority Data
Sep. 30, 2022 (JP) 2022-158678

(51) Int. Cl. H03K 17/687; H03F 3/217; H03K 17/10; H03K 19/0185

(52) U.S. Cl. CPC H03K 17/687; H03F 3/2171; H03K 17/102; H03K 19/018521; H03K 2217/0063

(57) ABSTRACT

The present disclosure provides a driving circuit of a high-side transistor. The driving circuit drives the high-side transistor based on an input signal. A level shift circuit is configured to level-shift the input signal. A high-side driver drives the high-side transistor based on an output of the level shift circuit. A first transistor and a second transistor constitute a latch circuit. A third transistor and a fourth transistor are P-channel DMOS transistors. A seventh transistor and an eighth transistor are N-channel DMOS transistors and are connected in parallel with the third transistor and the fourth transistor.

### CROSS REFERENCES TO RELATED APPLICATIONS

The present invention claims priority under 35 U.S.C. § 119 to Japanese Application No. 2022-158678, filed on Sep. 30, 2022, the entire contents of which being incorporated herein by reference.

### TECHNICAL FIELD

The present disclosure relates to a driving circuit of a high-side transistor.

### BACKGROUND

A level shift circuit is used in order to transmit and receive digital signals between two circuit blocks supplied with power supply voltages with different voltage levels. When a power supply voltage of a circuit block on a receiving side is higher, the level shift circuit is referred to as a level up-shift circuit; when a power supply voltage of a circuit block on a receiving side is lower, the level shift circuit is referred to as a level down-shift circuit.

### BRIEF DESCRIPTION OF THE DRAWINGS

FIG. 1 is a block diagram of a semiconductor integrated circuit having a high-side transistor.

FIG. 2 is a circuit diagram of a semiconductor integrated circuit including a level shift circuit of a comparison technique.

FIG. 3 is a circuit diagram of a semiconductor integrated circuit including a level shift circuit according to an embodiment.

FIG. 4 is a circuit diagram of a configuration example of a low voltage detection circuit and an auxiliary driver circuit.

FIG. 5 is a block diagram of a switch circuit in which a high-side transistor is a PMOS transistor.

FIG. 6 is a block diagram of an audio system.

FIG. 7 is a block diagram of a step-down converter.

FIG. 8 is a block diagram of a circuit system.

### DETAILED DESCRIPTION OF THE EMBODIMENTS

### Summary of Embodiments

A summary of several exemplary embodiments of the disclosure is provided below. The summary serves as the preamble of the detailed description provided hereinafter and aims to provide fundamental understanding of the embodiments by describing several concepts of one or more embodiments in brief. It should be noted that the summary is not to be construed as limitations to the scope of the application or disclosure. The summary is not a comprehensive summary of all conceivable embodiments, nor does it intend to specify important elements of all embodiments or to define the scope of a part of or all aspects. For the sake of better description, “one embodiment” sometimes refers to one embodiment (an implementation example or a variation example) or multiple embodiments (implementation examples or variation examples) disclosed in the present disclosure.

According to one embodiment, a driving circuit of a high-side transistor includes a level shift circuit configured to level shift an input signal, and a high-side driver configured to drive the high-side transistor based on an output of the level shift circuit. The level shift circuit includes: an output-side high-level line; an output-side low-level line; a first transistor, which is a PMOS transistor having a source connected to the output-side high-level line; a second transistor, which is a PMOS transistor having a source connected to the output-side high-level line; a third transistor, which is a PDMOS transistor, having a gate connected to the output-side low-level line and a source connected to a drain of the first transistor; a fourth transistor, which is a PDMOS transistor, having a gate connected to the output-side low-level line and a source connected to a drain of the second transistor; a fifth transistor, which is an NMOS transistor, connected between a drain of the third transistor and a ground; a sixth transistor, which is an NMOS transistor, connected between a drain of the fourth transistor and the ground; a seventh transistor, which is an NDMOS transistor, between the drain of the first transistor and the ground, and connected in parallel with the third and fifth transistors in series; an eighth transistor, which is an NDMOS transistor, between the drain of the second transistor and the ground, and connected in parallel with the fourth and sixth transistors in series; and an auxiliary driver circuit, configured to drive the seventh and eighth transistors according to the input signal during a voltage reduction.

When an input voltage supplied to a terminal of the high-side transistor reduces, the third transistor and the fourth transistor cannot be controlled, and the input signal cannot be transmitted to a latch circuit including the first transistor and the second transistor. In the low-voltage state, the input signal can be transmitted to the latch circuit by driving the seventh transistor and the eighth transistor, such that operations in the low-voltage state can be performed.

In one embodiment, the high-side transistor may be an NMOS transistor.

In one embodiment, the high-side transistor may also be a PMOS transistor.

In one embodiment, the driving circuit can be used in an in-vehicle machine. When a voltage input to the high-side transistor is lower than 10V, the auxiliary driver circuit becomes active.

In one embodiment, the driving circuit may be integrated on a single semiconductor substrate. The so-called “integrated” refers a situation in which all constituting elements including a circuit are formed on a semiconductor substrate, or a situation in which main constituting elements of a circuit are integrated. In order to adjust circuit constants, a part of resistors or capacitors may be arranged outside the semiconductor substrate. By integrating circuits on one chip, the circuit area can be reduced, and characteristics of circuit elements can be kept uniform.

In one embodiment, a class-D amplifier circuit includes a high-side transistor connected between an input line and an output line, a low-side transistor connected between the output line and a ground, and any one of the driving circuit driving the high-side transistor.

In one embodiment, a converter controller circuit is configured to control a step-down Direct Current/Direct Current (DC/DC) converter including a high-side transistor and a low-side transistor. The converter controller circuit includes a feedback circuit configured to generate a high-side pulse signal such that an output of the step-down DC/DC converter approaches a target state, and a driving circuit configured to drive the high-side transistor based on the high-side pulse signal.

In one embodiment, a high-side switch circuit includes an input terminal, an output terminal, a control terminal, a high-side transistor connected between the input terminal and the output terminal, and a driving circuit configured to drive the high-side transistor based on a signal input to the control terminal.

### EMBODIMENTS

Details of appropriate embodiments are provided with the accompanying drawings below. The same or equivalent constituting elements, parts and processes are represented by the same denotations, and repeated description is omitted as appropriate. Moreover, the embodiments are illustrative and are not restrictive of the disclosure. All features and combinations thereof described in the embodiments are not necessarily intrinsic characteristics of the disclosure.

Moreover, for better understanding, the dimensions (thickness, length, and width) of each component in the accompanying drawings may be appropriately scaled up or scaled down. In addition, the dimensions of the multiple components do not necessarily represent their dimensional relations, and even if a component A may be depicted to appear thicker than a component B in the drawings, it is possible that the component A is thinner than the component B.

In the present disclosure, an expression “a state of a component A connected to a component B” also includes, in addition to a situation where the component A and the component B are directly connected, a situation where the component A is indirectly connected to the component B via another component, and the indirect connection does not result in substantial influences on their electrical connection or does not impair functions or effects exerted by their combination.

Similarly, an expression “a state of a component C connected (arranged) between a component A connected to a component B” also includes, in addition to a situation where the component A and the component C, or the component B and the component C are directly connected, an indirect connection via another component, and the indirect connection does not result in substantial influences on their electrical connection or does not impair functions or effects exerted by their combination.

Moreover, in the present disclosure, denotations assigned to electrical signals such as voltage signals and current signals, and circuit elements such as resistors, capacitors and inductors stand for respective voltage values, current values or circuit constants (resistance values, capacitance values and inductance values) as needed.

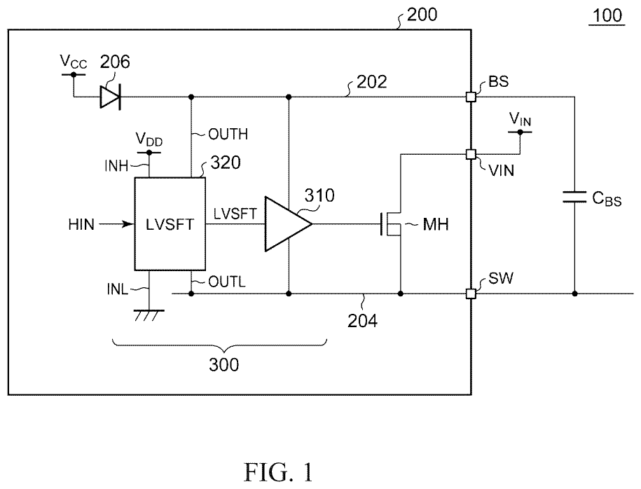

FIG. 1 shows a block diagram of a switch circuit 100 having a high-side transistor. An input voltage V_{IN} is supplied to an input pin V_{IN} of a semiconductor integrated circuit 200. The semiconductor integrated circuit 200 includes a high-side transistor MH and a driving circuit 300. In FIG. 1, the high-side transistor MH is an N-channel metal oxide semiconductor field effect transistor (MOSFET), which has a drain connected to the input pin V_{IN} and a source connected to a switch pin SW.

The driving circuit 300 drives the high-side transistor MH according to an input signal HIN. For example, the driving circuit 300 turns on the high-side transistor MH when the input signal HIN is high and turns off the high-side transistor MH when the input signal HIN is low. The input signal HIN is a digital signal that sets a power supply voltage V_{DD} to a high level and a ground voltage to a low level.

A bootstrap capacitor C_{BS} is externally arranged between a bootstrap pin BS and the switch pin SW. The bootstrap capacitor C_{BS} and a rectifier element 206 form a bootstrap circuit. The rectifier element 206 is a diode, which has a cathode connected to a bootstrap line 202, and an anode receiving a power supply voltage V_{CC}. The rectifier element 206 may also be a synchronous rectifier switch that is switched synchronously with the high-side transistor MH.

A level shift circuit 320 receives the input signal HIN and generates a control signal LVSFT that sets a voltage V_{BS} of the bootstrap line 202 to a high level and a voltage of a switch line 204 to a low level. The level shift circuit 320 includes a high-level line INH and a low-level line INL of an input side, and a high-level line OUTH and a low-level line OUTL of an output side. The high-level line INH and the low-level line INL of the input side are supplied with a voltage corresponding to a high-level voltage and a low-level voltage of the input signal. The high-level line OUTH and the low-level line OUTL of the output side are supplied with a voltage corresponding to the high-level voltage and the low-level voltage of the output signal LVSFT of the level shift circuit 320.

A high-side driver 310 drives the high-side transistor MH based on the level shifted control signal LVSFT.

The configuration of the switch circuit 100 is as described above.

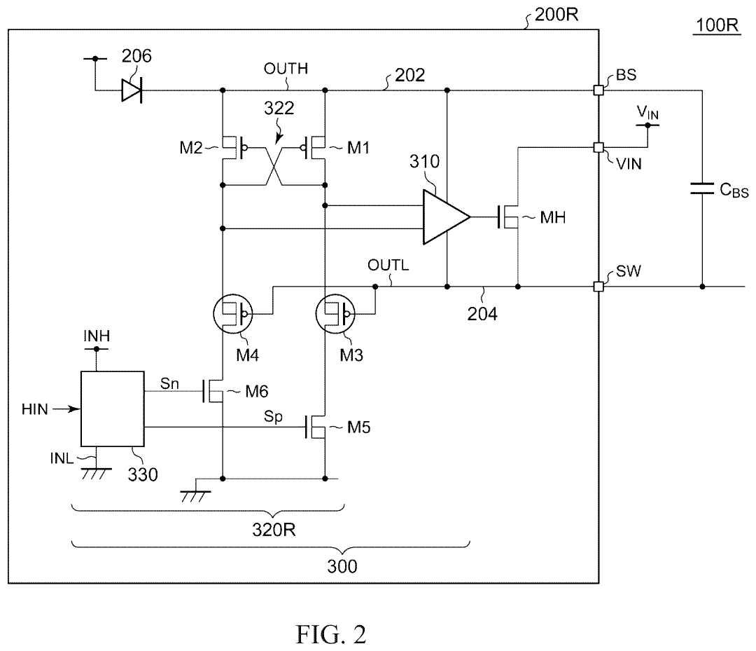

FIG. 2 shows a circuit diagram of a semiconductor integrated circuit 200R including a level shift circuit 320R of a comparison technique. The level shift circuit 320R includes a first transistor M1 to a sixth transistor M6 and a driver circuit 330.

A source of each of the first transistor M1 and the second transistor M2 is connected to the bootstrap line 202. A gate of the first transistor M1 is connected to a drain of the second transistor M2, a gate of the second transistor M2 is connected to a drain of the first transistor M1, and the first transistor M1 and the second transistor M2 connected in a lopsided cross manner form a latch circuit 322.

A source of each of the fifth transistor M5 and the sixth transistor M6 is connected to a ground. The third transistor M3 is inserted between the first transistor M1 and the fifth transistor M5 in order to provide withstand voltage protection. Similarly, the fourth transistor M4 is inserted between the second transistor M2 and the sixth transistor M6 in order to provide withstand voltage protection. The third transistor M3 and the fourth transistor M4 are P-channel double-diffused metal-oxide semiconductor (DMOS) transistors. A gate of each of the third transistor M3 and the fourth transistor M4 is connected to the switch line 204. The fifth transistor M5 and the sixth transistor M6 may be implemented by DMOS transistors.

The driver circuit 330 turns on the fifth transistor M5 in response to a rising edge of the input signal HIN and turns off the sixth transistor M6 in response to a falling edge of the input signal HIN. For example, the driver circuit 330 may set a control signal Sp to a high level and a control signal Sn to a low level when the input signal HIN is at a high level and set the control signal Sp to a low level and the control signal Sn to a high level when the input signal HIN is at a low level. Alternatively, the driver circuit 330 may set the control signal Sp to a high level within a predetermined time period starting from a rising edge of the input signal HIN and set the control signal Sn to a high level within a predetermined time period starting from a falling edge of the input signal HIN. The configuration of the driver circuit 330 is not specifically defined.

The level shift circuit 320R in FIG. 2 operates correctly when the input voltage V_{IN} is sufficiently high (for example, V_{IN}>10 V). However, when the input voltage V_{IN} is lower than 10 V, signals cannot be correctly transmitted through the DMOS transistors, that is, the third transistor M3 and the fourth transistor M4, to the latch circuit 322.

Thus, it may be difficult to use the level shift circuit 320R in FIG. 2 in applications where the input voltage V_{IN} is lower than 10 V.

Next, a level shift circuit 320A capable of operating in a low voltage is described below.

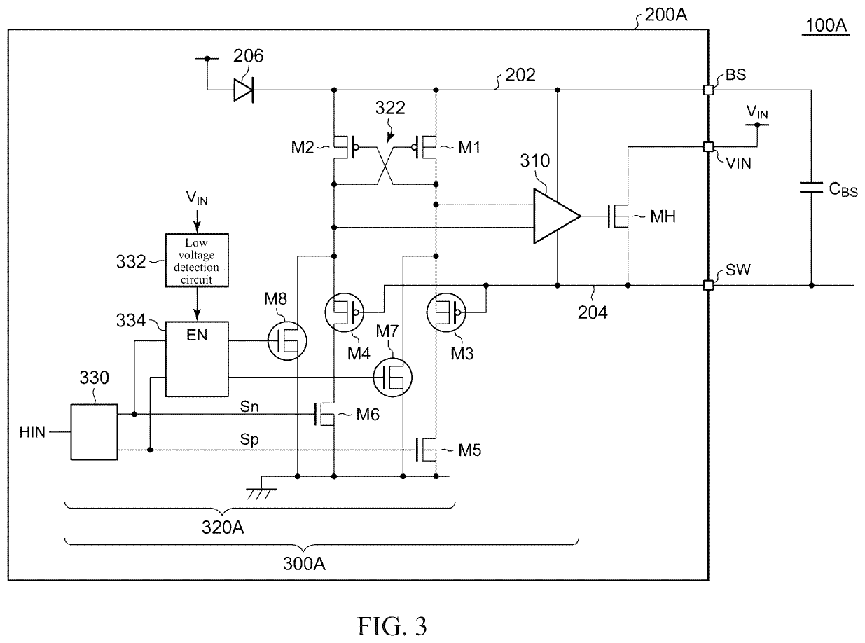

FIG. 3 shows a circuit diagram of a semiconductor integrated circuit 200A including the level shift circuit 320A according to an embodiment. In addition to the level shift circuit 320R in FIG. 2, the level shift circuit 320A further includes a seventh transistor M7, an eighth transistor M8, a low voltage detection circuit 332 and an auxiliary driver circuit 334.

The low voltage detection circuit 322 monitors the input voltage V_{IN} and asserts a low voltage detection signal UVLO (for example, setting it to a high level) when the input voltage V_{IN} is lower than a predetermined threshold voltage VTH

When the low voltage detection signal UVLO is asserted, the auxiliary driver circuit 334 drives the seventh transistor M7 according to the control signal Sp and drives the eighth transistor M8 according to the control signal Sn.

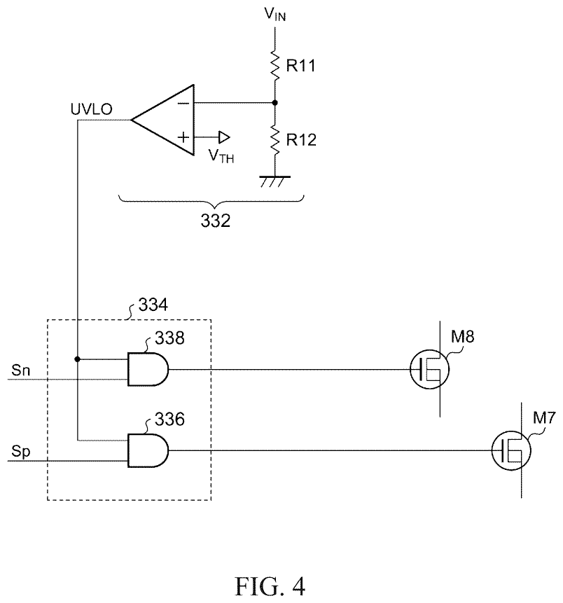

FIG. 4 shows a circuit diagram of a configuration example of the low voltage detection circuit 332 and the auxiliary driver circuit 334. The low voltage detection circuit 332 includes a voltage comparator COMP1, and resistors R11 and R12. The resistors R11 and R12 divide the input voltage V_{IN}. The voltage comparator COMP1 compares a divided input voltage V_{IN′} with the threshold voltage VTH to generate the low voltage detection signal UVLO indicating the comparison result.

The auxiliary driver circuit 334 may be formed by a combination of logic gates. For example, the auxiliary driver circuit 334 may include 2 AND gates 336 and 338. The AND gate 336 generates a logical product of the low voltage detection signal UVLO and the control signal Sp and supplies the logical product to a gate of the seventh transistor M7. The AND gate 338 generates a logical product of the low voltage detection signal UVLO and the control signal Sn and supplies the logical product to a gate of the eighth transistor M8. A buffer may be additionally arranged between an output of the AND gate 336 and a gate of the seventh transistor M7.

The configuration of the semiconductor integrated circuit 200A according to an embodiment is as described above.

In the semiconductor integrated circuit 200A, if the third transistor M3 and the fourth transistor M4 cannot be controlled when the input voltage V_{IN} reduces, the auxiliary driver circuit 334 becomes active. The auxiliary driver circuit 334 in an active state turns on the seventh transistor M7 when the control signal Sp is asserted. Accordingly, a low level is applied to the gate of the second transistor M2, and the latch circuit 322 changes to a first state. Moreover, the auxiliary driver circuit 334 in an active state turns on the eighth transistor M8 when the control signal Sn is asserted. Accordingly, a low level is applied to the gate of the first transistor M1, and the latch circuit 322 changes to a second state.

As such, even in a low voltage state, the level shift circuit 320A according to the embodiment is capable of generating a change in the state of the latch circuit 322 corresponding to the input signal HIN, hence preventing inoperability.

The high-side transistor MH may also be a PMOS transistor.

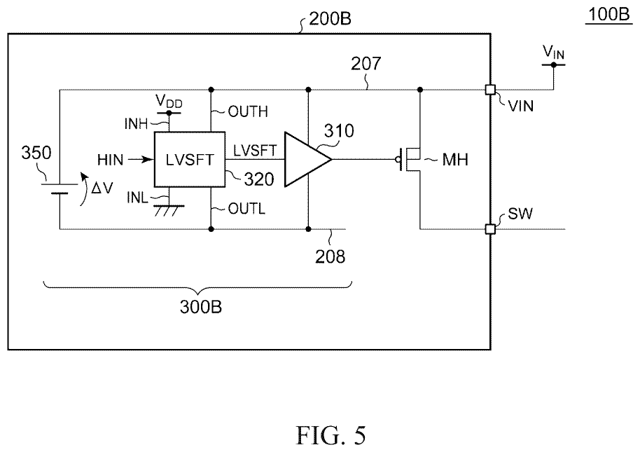

FIG. 5 shows a block diagram of a switch circuit 100B in which a high-side transistor is a PMOS transistor. A semiconductor integrated circuit 200B includes the high-side transistor MH implemented by a PMOS transistor. An input line 207 is connected to the high-level line OUTH of the output side of the level shift circuit 320, and a low-level line 208 is connected to the low-level line OUTL of the output side of the level shift circuit 320. A constant voltage circuit 350 stabilizes the voltage of the low-level line 208 to a voltage level that is less than the input voltage V_{IN} by a fixed voltage ΔV.

Even when the high-side transistor MH is a PMOS transistor, the level shift circuit 320 can be implemented by the level shift circuit 320A. Thus, when the input voltage V_{IN} is a low voltage, the high-side transistor MH can still be driven based on the input signal HIN.

Next, the use of a switch circuit is described.

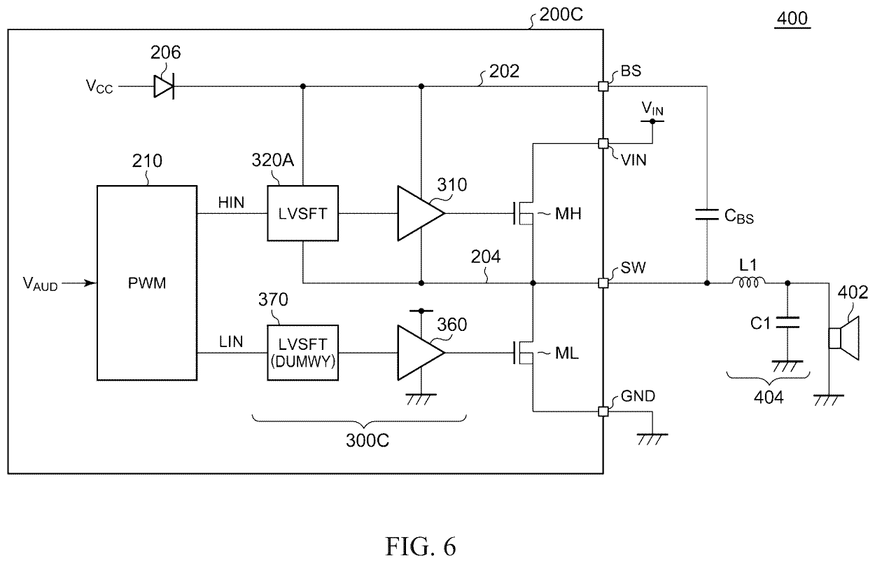

FIG. 6 shows a block diagram of an audio system 400. The audio system 400 includes an audio integrated circuit (IC) 200C, a speaker 402, a filter 404 and a bootstrap capacitor C_{BS}.

The audio IC 200C is a class-D amplifier, and includes a high-side transistor MH, a low-side transistor ML, a driving circuit 300C, and a pulse width modulator 210. The high-side transistor MH is connected between the input pin V_{IN} and the switch pin SW, and the low-side transistor ML is connected between the switch pin SW and a ground pin GND.

The pulse width modulator 210 converts an audio signal VAUD to a pulse width modulation (PWM) signal, and generates control signals HIN and LIN.

The control signal HIN is up-shifted by the level shift circuit 320A and supplied to the high-side driver 310.

A level shift circuit 370 is provided as a dummy in order to keep the amounts of delay of the high side and the low side consistent. The level shift circuit 370 may also be omitted. A low-side driver 360 drives the low-side transistor ML according to an output of the level shift circuit 370.

The audio system 400 may also be used in a vehicle. In this case, a battery voltage V_{BAT} is supplied to the input pin V_{IN} as the input voltage V_{IN}. The battery voltage V_{BAT} of an in-vehicle battery has a rated value of 12 V to 14 V; however, operations of the audio IC 200C can be maintained even when the battery voltage V_{BAT} reduces to below 10 V.

According to the audio system 400 in FIG. 6, by using the level shift circuit 320A, audio signals can still be played even when the battery voltage V_{BAT} is low.

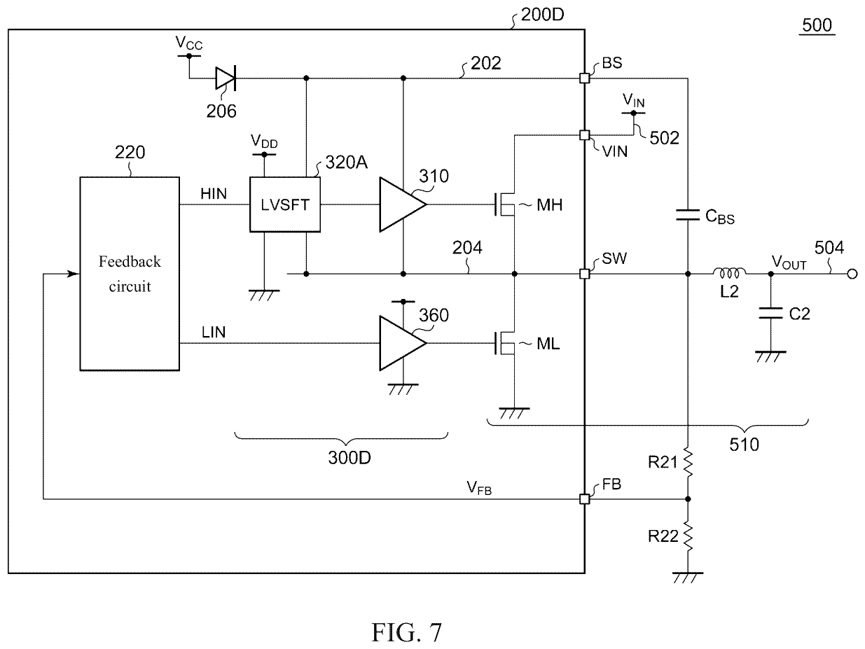

FIG. 7 shows a block diagram of a step-down converter 500. The step-down converter 500 includes a controller IC 200D and a main circuit 510 of the step-down converter. The step-down converter 500 steps down an input voltage V_{IN} of an input line 502 to an output voltage V_{OUT} having a predetermined voltage level and supplies the same to a load (not shown) connected to an output line 504. The main circuit 510 includes a high-side transistor MH, a low-side transistor ML, an inductor L2 and an output capacitor C2.

The controller IC 200D includes a driving circuit 300D and a feedback circuit 220. Resistors R21 and R22 divide the output voltage V_{OUT}, and a divided feedback voltage V_{FB} is supplied to a feedback pin FB of the controller IC 200D.

The feedback circuit 220 generates a PWM signal for adjusting a duty cycle coefficient such that the feedback voltage V_{FB} approaches a predetermined reference voltage V_{REF} The feedback circuit 220 generates control signals HIN and LIN according to the PWM signal. The level shift circuit 320A level shifts the control signal HIN and supplies the level-shifted control signal HIN to the high-side driver 310. Moreover, the control signal LIN is directly supplied to a low-side driver 360. A dummy level shift circuit may be inserted between the feedback circuit 220 and the low-side driver 360.

The step-down converter 500 may also be a diode rectifier-type, and in this case, a rectifier diode is connected in substitution for the low-side transistor ML to omit the low-side driver 360.

The step-down converter 500 may also be used in a vehicle. In this case, a battery voltage V_{BAT} is supplied to the input pin V_{IN} as the input voltage V N. The battery voltage V_{BAT} of an in-vehicle battery has a rated value of 12 V to 14 V; however, operations of the step-down converter 500 can be maintained even when the battery voltage V_{BAT} reduces to below 10 V.

According to the step-down converter 500 in FIG. 7, by using the level shift circuit 320A, the output voltage V_{OUT} can still be stabilized to a target level even when the battery voltage V_{BAT} is low.

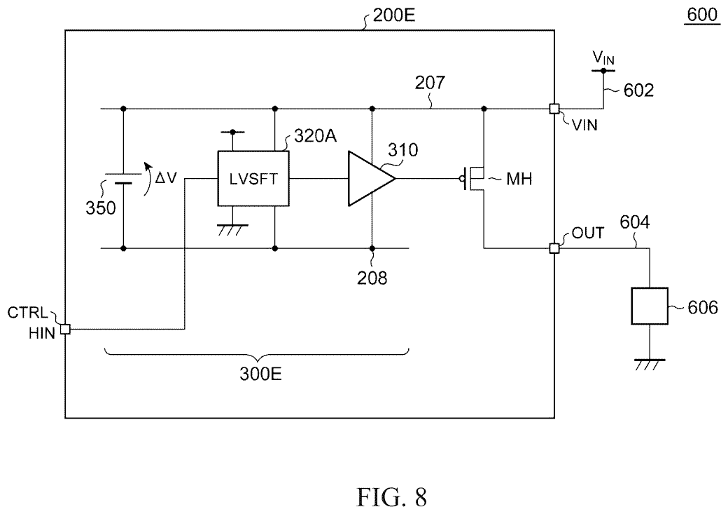

FIG. 8 shows a block diagram of a circuit system 600. The circuit system 600 includes a high-side switch IC 200E. The high-side switch IC 200E receives from the outside a control signal HIN at a control pin CTRL. An input voltage V_{IN} is supplied to an input pin VIN of the high-side switch IC 200E through an input line 602, and a load circuit 606 is connected to an output pin OUT. The high-side switch IC 200E includes a high-side transistor MH and a driving circuit 300E. The driving circuit 300E turns on the high-side transistor MH when the control signal HIN is at an on-level (for example, a high level). At this point in time, in the output pin OUT, an output voltage V_{OUT} having a voltage level substantially equal to that of the input voltage V_{IN} is generated. The driving circuit 300E turns off the high-side transistor MH when the control signal HIN is at an off-level (for example, a low level). At this point in time, the output pin OUT becomes in a high-impedance state.

### (Notes)

The present disclosure discloses the following techniques.
(Item 1)

A driving circuit of a high-side transistor, comprising:
a level shift circuit, configured to level shift an input signal; and a high side driver, configured to drive the high-side transistor based on an output of the level shift circuit, wherein the level shift circuit includes:
   an output-side high-level line;
   an output-side low-level line;
   a first transistor, which is a P-channel (PMOS) transistor having a source connected to the output-side high-level line;
   a second transistor, which is a PMOS transistor having a source connected to the output-side high-level line;
   a third transistor, which is a P-channel double-diffused MOS (PDMOS) transistor, having a gate connected to the output-side low-level line and a source connected to a drain of the first transistor;
   a fourth transistor, which is P-channel double-diffused MOS (PDMOS) transistor, having a gate connected to the output-side low-level line and a source connected to a drain of the second transistor;
   a fifth transistor, which is an N-channel MOS (NMOS) transistor, connected between a drain of the third transistor and a ground;
   a sixth transistor, which is an NMOS transistor, connected between a drain of the fourth transistor and the ground;
   a seventh transistor, which is an N-channel double-diffused MOS (NDMOS) transistor, between the drain of the first transistor and the ground, and connected in parallel with the third and fifth transistors in series;
   an eighth transistor, which is an NDMOS transistor, between the drain of the second transistor and the ground, and connected in parallel with the fourth and sixth transistors in series; and
   an auxiliary driver circuit, configured to drive the seventh and eighth transistors according to the input signal during a voltage reduction.
(Item 2)

The driving circuit of item 1, wherein the high-side transistor is an NMOS transistor.
(Item 3)

The driving circuit of item 1, wherein the high-side transistor is a PMOS transistor.
(Item 4)

The driving circuit of any one of items 1 to 3, wherein the driving circuit is used in an in-vehicle machine, and when a voltage input to the high-side transistor is lower than 10V, the auxiliary driver circuit becomes active.
(Item 5)

A class-D amplifier circuit, comprising:
a high-side transistor, connected between an input line and an output line;
a low-side transistor, connected between the output line and a ground; and
the driving circuit of any one of items 1 to 4, configured to drive the high-side transistor.
(Item 6)

A converter controller circuit, which is configured to control a step-down DC/DC converter including a high-side transistor and a low-side transistor, the converter controller circuit comprising:
a feedback circuit, configured to generate a high-side pulse signal such that an output of the step-down DC/DC converter approaches a target state; and
the driving circuit of any one of items 1 to 4, configured to drive the high-side transistor based on the high-side pulse signal.
(Item 7)

A high-side switch circuit, comprising:
an input terminal;
an output terminal;
a control terminal;
a high-side transistor, connected between the input terminal and the output terminal; and
the driving circuit of any one of items 1 to 4, wherein the high-side transistor is driven based on a signal input to the control terminal.

Although specific terms are used to describe the embodiments of the present disclosure, it is to be noted that the descriptions above only provide illustrations for better understanding and are not to be construed as limitations to the present disclosure or the scope of the appended claims. The scope of the present disclosure is defined by the appended claims, and therefore implementations, embodiments and variation examples not described herein are also encompassed within the scope of the present disclosure.

1. A driving circuit of a high-side transistor, comprising:
a level shift circuit, configured to level shift an input signal; and
a high side driver, configured to drive the high-side transistor based on an output of the level shift circuit, wherein the level shift circuit includes:
an output-side high-level line;
an output-side low-level line;
a first transistor, which is PMOS transistor having a source connected to the output-side high-level line;
a second transistor, which is PMOS transistor having a source connected to the output-side high-level line;
a third transistor, which is PDMOS transistor, having a gate connected to the output-side low-level line and a source connected to a drain of the first transistor;
a fourth transistor, which is PDMOS transistor, having a gate connected to the output-side low-level line and a source connected to a drain of the second transistor;
a fifth transistor, which is NMOS transistor, connected between a drain of the third transistor and a ground;
a sixth transistor, which is NMOS transistor, connected between a drain of the fourth transistor and the ground;
a seventh transistor, which is NDMOS transistor, between the drain of the first transistor and the ground, and connected in parallel with the third and fifth transistors in series;
an eighth transistor, which is NDMOS transistor, between the drain of the second transistor and the ground, and connected in parallel with the fourth and sixth transistors in series; and
an auxiliary driver circuit, configured to drive the seventh and eighth transistors according to the input signal during a voltage reduction.

2. The driving circuit of claim 1, wherein the high-side transistor is NMOS transistor.

3. The driving circuit of claim 1, wherein the high-side transistor is PMOS transistor.

4. The driving circuit of claim 1, wherein the driving circuit is used in a vehicle machine, and when a voltage input to the high-side transistor is lower than 10V, the auxiliary driver circuit becomes active.

5. The driving circuit of claim 2, wherein the driving circuit is used in a vehicle machine, and when a voltage input to the high-side transistor is lower than 10V, the auxiliary driver circuit becomes active.

6. The driving circuit of claim 3, wherein the driving circuit is used in a vehicle machine, and when a voltage input to the high-side transistor is lower than 10V, the auxiliary driver circuit becomes active.

7. A class-D amplifier circuit, comprising:
a high-side transistor, connected between an input line and an output line;
a low-side transistor, connected between the output line and a ground; and
the driving circuit of claim 1, configured to drive the high-side transistor.

8. A class-D amplifier circuit, comprising:
a high-side transistor, connected between an input line and an output line;
a low-side transistor, connected between the output line and a ground; and
the driving circuit of claim 2, configured to drive the high-side transistor.

9. A class-D amplifier circuit, comprising:
a high-side transistor, connected between an input line and an output line;
a low-side transistor, connected between the output line and a ground; and
the driving circuit of claim 3, configured to drive the high-side transistor.

10. A converter controller circuit, which is configured to control a step-down DC/DC converter including a high-side transistor and a low-side transistor, the converter controller circuit comprising:
a feedback circuit, configured to generate a high-side pulse signal such that an output of the step-down DC/DC converter approaches a target state; and
the driving circuit of claim 1, configured to drive the high-side transistor based on a high-side pulse signal.

11. A converter controller circuit, which is configured to control a step-down DC/DC converter including a high-side transistor and a low-side transistor, the converter controller circuit comprising:
a feedback circuit, configured to generate a high-side pulse signal such that an output of the step-down DC/DC converter approaches a target state; and
the driving circuit of claim 2, configured to drive the high-side transistor based on a high-side pulse signal.

12. A converter controller circuit, which is configured to control a step-down DC/DC converter including a high-side transistor and a low-side transistor, the converter controller circuit comprising:
a feedback circuit, configured to generate a high-side pulse signal such that an output of the step-down DC/DC converter approaches a target state; and
the driving circuit of claim 3, configured to drive the high-side transistor based on a high-side pulse signal.

13. A high-side switch circuit, comprising:
an input terminal;
an output terminal;
a control terminal;
a high-side transistor, connected between the input terminal and the output terminal; and
the driving circuit of claim 1, wherein the high-side transistor is driven based on a signal input to the control terminal.

14. A high-side switch circuit, comprising:
an input terminal;
an output terminal;
a control terminal;
a high-side transistor, connected between the input terminal and the output terminal; and
the driving circuit of claim 2, wherein the high-side transistor is driven based on a signal input to the control terminal.

15. A high-side switch circuit, comprising:
an input terminal;
an output terminal;
a control terminal;
a high-side transistor, connected between the input terminal and the output terminal; and
the driving circuit of claim 3, wherein the high-side transistor is driven based on a signal input to the control terminal.
